(19) United States
(12) Patent Application Publication
(10) Pub. No.: US 2025/0253152 A1
(43) Pub. Date: Aug. 7, 2025

(54) DIRECT CURRENT SUPERPOSITION (DCS) FOR PROTECTION OF ORGANIC MANDREL DURING SPACER DEPOSITION

(71) Applicant: Tokyo Electron Limited, Tokyo (JP)

(72) Inventors: Katie LUTKER-LEE, Albany, NY (US); Christopher COLE, Albany, NY (US)

(73) Assignee: Tokyo Electron Limited, Tokyo (JP)

(21) Appl. No.: 18/433,320

(22) Filed: Feb. 5, 2024

(51) Int. Cl. H01L 21/033

(52) U.S. Cl. CPC H01L 21/0337

(57) ABSTRACT

Methods of manufacturing a semiconductor device are disclosed. The method includes providing a structure comprising an organic mandrel formed in a pattern and an underlying layer. The method includes hardening the organic mandrel including forming a silicon-based layer along an outer portion of the organic mandrel. The method includes depositing a spacer layer over the hardened organic mandrel.

### FIELD OF THE DISCLOSURE

This disclosure relates to systems and methods for substrate processing, including methods for protecting organic mandrel during spacer deposition.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate.

### SUMMARY

There is an ongoing demand for scaling down feature sizes of semiconductor devices. In some scenarios, because of the shrinking of feature sizes, carbon or soft mandrel materials may transition or be replaced with relatively harder alternatives, e.g., relatively harder mandrel materials, such as silicon nitride or amorphous silicon. However, it may be challenging to remove these relatively harder materials given the material selectivity compared to the softer alternatives (or counterparts). In some cases, the use of carbon-based mandrels may potentially pose certain challenges or issues downstream, e.g., in subsequent processes for fabricating the semiconductor devices, such as during deposition steps. For example, the potential challenges may include the collapse or etched-out of the carbon materials during the deposition steps. In such cases, the potential downstream challenges may render the carbon-based mandrel unsuitable for current applications.

The techniques described herein include methods and devices for protecting of organic mandrel during spacer deposition. Specifically, the techniques can provide methods and devices for direct current superposition (DCS) for the protection of organic mandrel during spacer deposition. For example, the techniques can provide a patterned structure including an underlying layer and a mandrel (e.g., organic mandrel or soft mandrel). The mandrel can be formed of any suitable material, such as but not limited to carbon. The mandrel can be deposited above the underlying layer and patterned using at least one suitable etching technique. With the patterned mandrel, the systems and methods can perform the DCS treatment for the mandrel to protect the mandrel from subsequent operations. The DCS treatment can deposit or form a protective layer (e.g., a thin layer) of silicon along the outer layer of the mandrel, thereby hardening at least the outer layer or portions of the mandrel. Hence, by forming the protective layer along the outer layer of the mandrel, the systems and methods can improve the structural integrity and protect the mandrel during spacer deposition and other subsequent fabrication stages of a semiconductor device.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a method for spacer deposition. The method can include providing a structure comprising an organic mandrel formed in a pattern and an underlying layer. The method can include hardening the organic mandrel including forming a silicon-based layer along an outer portion of the organic mandrel. The method can include depositing a spacer layer over the hardened organic mandrel.

The method can include etching a first portion of the spacer layer to expose a top surface of the organic mandrel. The method can include etching a second portion of the spacer layer to expose portions of a top surface of the underlying layer, wherein the spacer layer remaining on the structure functions as a hard mask. The method can include removing the organic mandrel from the structure to pattern the underlying layer.

To provide the structure, the method can include forming the underlying layer above a substrate. The method can include forming the organic mandrel above the underlying layer. The method can include etching the organic mandrel to form the pattern.

The silicon-based layer can be formed through at least one of a DCS plasma treatment process or a chemical vapor deposition (CVD) treatment process. The organic mandrel can include carbon. The silicon-based layer can include at least one of silicon, silicon dioxide, silicon nitride, or silicon oxynitride. The silicon-based layer may become oxidized during the process or after due to airbrake.

Forming the structure can be performed in a first chamber. Hardening the organic mandrel can be performed in a second chamber. Depositing the spacer layer can be performed in a third chamber. The first chamber may be same as the second chamber, and the second chamber may be different from the third chamber. The first chamber may be different from the second chamber, and the second chamber may be different from the third chamber. The spacer layer can include at least one of silicon oxide, silicon nitride, titanium oxide, or titanium nitride.

At least one aspect of the present disclosure is directed to a method for spacer deposition. The method can include providing a patterned structure comprising an organic mandrel and an underlying layer. The method can include forming a protective layer along an outer portion of the organic mandrel to harden the organic mandrel. The method can include depositing a spacer layer over the patterned structure including the protective layer formed along the outer portion of the organic mandrel.

The method can include etching the spacer layer to expose a top surface of the organic mandrel and portions of a top surface of the underlying layer, wherein the spacer layer remaining on sides of the organic mandrel functions as a hard mask. The method can include removing the organic mandrel from the patterned structure to pattern the underlying layer.

To provide the patterned structure, the method can include forming the underlying layer above a substrate. The method can include forming the organic mandrel above the underlying layer. The method can include etching the organic mandrel to form a pattern.

The protective layer can be formed through at least one of a DCS plasma treatment process, an UV light treatment process, or a CVD treatment process. The organic mandrel can include carbon. The protective layer may correspond to a silicon-based layer.

Yet another aspect of the present disclosure is directed to a method for spacer deposition. The method can include providing, via a first chamber, a structure comprising an organic mandrel formed in a pattern and an underlying layer. The method can include hardening, via a second chamber, the organic mandrel based on forming a silicon-based layer along an outer portion of the organic mandrel. The method can include depositing, via a third chamber, a spacer layer over the hardened organic mandrel.

The first chamber may be same as the second chamber, and the second chamber may be different from the third chamber. The first chamber may be different from the second chamber, and the second chamber may be different from the third chamber. The silicon-based layer can include at least one of silicon dioxide, silicon nitride, or silicon oxynitride, and wherein the spacer layer includes at least one of silicon oxide, silicon nitride, titanium oxide, or titanium nitride.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow diagram for a process flow to perform DCS treatment for protecting an organic mandrel during spacer deposition, according to an embodiment; and

FIGS. 2A-6 show various views of a process flow to perform DCS treatment for protecting the organic mandrel during spacer deposition, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for protecting the mandrel during subsequent operations, such as spacer deposition or patterning the features of the semiconductor device. Specifically, techniques include applying or performing a DCS treatment on the mandrel to protect the mandrel during subsequent operations (e.g., fabricating or processing operations), such as spacer deposition. For example, the techniques can provide a patterned structure including an underlying layer and a mandrel (e.g., organic mandrel or soft mandrel). The mandrel can be formed of any suitable material, such as but not limited to carbon. The mandrel can be deposited above the underlying layer and patterned using at least one suitable etching technique. With the patterned mandrel, the systems and methods can perform the DCS treatment for the mandrel to protect the mandrel from subsequent operations. The DCS treatment can deposit or form a protective layer of silicon (e.g., sometimes referred to as a silicon-based layer) along the outer layer of the mandrel. The DCS treatment can modify or strengthen the mandrel, such as along with the deposition of the silicon layer to harden at least the outer layer or portions of the mandrel. Therefore, by using the DCS treatment to form the protective layer along the outer layer of the mandrel and/or strengthen the mandrel, the systems and methods can improve the structural integrity and protect the mandrel during spacer deposition and other subsequent fabrication stages of a semiconductor device.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

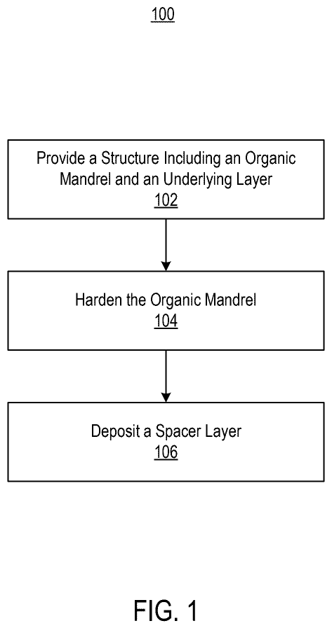

FIG. 1 illustrates a flowchart of an example method 100 for spacer deposition. The method 100 can be a part of forming a semiconductor device. For example, the semiconductor device can include or be composed of various suitable materials not limited to those as discussed herein. The materials can be deposited, etched, or otherwise constructed to form one or more desired structures. The method 100 can include executing at least one suitable deposition technique to deposit at least one material to form the structure, such as but not limited to at least one of physical vapor deposition (PVD), chemical vapor deposition (CVD), electroplating, spin-coating, or so forth. The method 100 can include executing at least one suitable etching technique to etch, remove, or otherwise pattern at least a portion of the structure, such as but not limited to at least one of dry etching, wet etching, plasma etching, chemical mechanical polishing (CMP), or other etching techniques. The method 100 can include the execution of other techniques or operations to fabricate the semiconductor device.

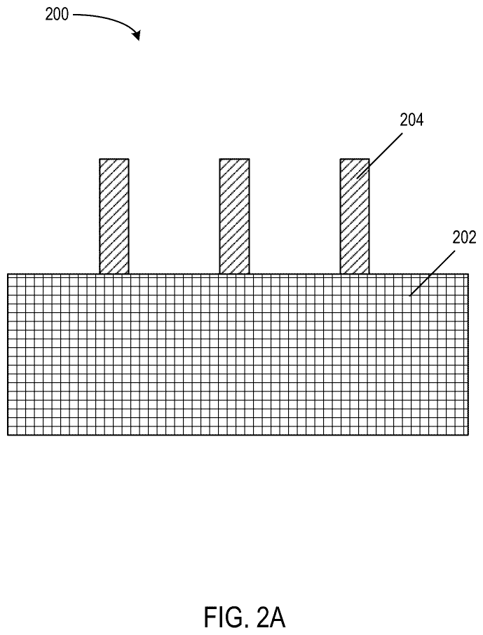

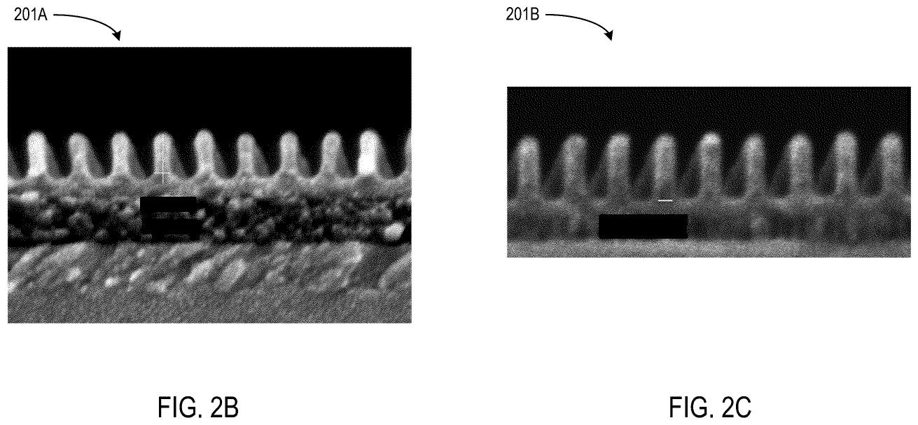

In various embodiments, operations of the method 100 may be associated with top, cross-sectional, perspective, or other views of an example semiconductor device at various fabrication stages as shown in at least FIGS. 2A-6, which will be discussed in further detail below. It should be understood that the semiconductor device (or structures of the semiconductor device), shown in FIGS. 2A-6, may include a number of other devices such as inductors, fuses, capacitors, coils, etc., while remaining within the scope of the present disclosure. For example, a semiconductor device can include further layers of stacked transistors or channel portions thereof, interconnections therebetween, or portions thereon.

In brief overview, the method 100 includes at least but not limited to operations 102-106. At operation 102, the method 100 includes providing or forming a structure including an underlayer 202 and a mandrel 204. At operation 104, the method 100 includes curing or hardening the mandrel 204. At operation 106, the method 100 includes depositing or forming a spacer layer 208. According to various embodiments, various operations of the method 100 may be omitted, added, modified, or combined. The operations of the method 100 may be performed sequentially or concurrently. The operations of the method 100 can be performed in other order or sequence, not limited to those described herein.

Corresponding to operation 102 of FIG. 1, FIGS. 2A-C show a cross-sectional view 200 and side views 201A-B of an example structure of the semiconductor device formed in a chamber. The side views 201A-B can present images of the example structure captured by an imaging device (e.g., at a microscopic level). The chamber for forming the structure can be referred to as a processing chamber (e.g., a first chamber). The provided structure can include an underlayer 202 and a mandrel 204. The underlayer 202 may be referred to as an underlying layer. The mandrel 204 may be referred to as an organic mandrel or a soft mandrel.

As shown in at least FIGS. 2A-C, the structure can include the mandrel 204 deposited over the underlayer 202. The mandrel 204 can be patterned to provide a patterned structure. For example, in the processing chamber, an underlayer 202 can be deposited above a substrate (not shown) using at least one suitable deposition technique. The substrate can include or be composed of any suitable material, such as but not limited to silicon (Si), gallium arsenide (GaAs), polymer, etc. The underlayer 202 can include or be composed of any suitable material, such as silicon dioxide (SiO₂), silicon nitride (Si₃N₄), polysilicon, etc. In some cases, the substrate can be formed with at least one material similar to the underlayer 202. In some other cases, the underlayer 202 can correspond to or be a part of the substrate.

The mandrel 204 can be deposited over the underlayer 202 via at least one suitable deposition technique in the processing chamber. The mandrel 204 can be composed of at least one suitable material. For the purposes of providing examples herein, the mandrel 204 can include or be composed of carbon or other soft materials. The mandrel 204 can be used for creating patterns, voids, or specific structures in the semiconductor device.

For example, subsequent to depositing the mandrel 204, the mandrel 204 can be etched using at least one suitable etching technique. To perform the etching, a mask (e.g., hard mask or photoresist layer) can be applied over the mandrel 204. The mask can include pre-configured openings or gaps defining the pattern. Responsive to applying the mask, an etching process can be executed using the suitable etching technique to remove the exposed areas of the mandrel 204, thereby forming a pattern shown in at least but not limited to FIGS. 2A-C. As discussed herein, to etch the materials of the semiconductor device, the mask defining a pattern can be deposited before the etching process, and removed after performing the etching process.

The structure including the patterned mandrel 204 can be referred to as a patterned structure. The patterned structure can be provided in the processing chamber. In some cases, the mandrel 204 can comprise a resist, an organic planarizing layer (OPL), an advanced pattern film (APF), and/or a spin-on hardmask (SOH). Other materials can be included as part of the mandrel, including but not limited to silicon containing anti-reflective coating (SiARC), bottom anti-reflective coating (BARC), low-temperature oxide (LTO), and/or silicon oxynitride (SiON) layer under the resist, for example. The APF can include chemical vapor deposition (CVD) amorphous carbon film with high carbon content and some hydrogen. The SOH can include spin-on organic polymer carbon content greater than 90%. The OPL can include compositions of C/H/O/N 81.6/4.6/9.9/3.9 wt % or compositions of C/H/O/N 85.4/5.8/6.0/2.9 wt %, for example.

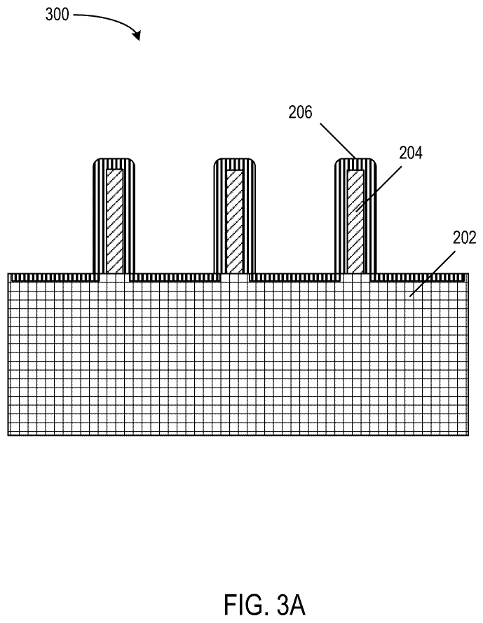

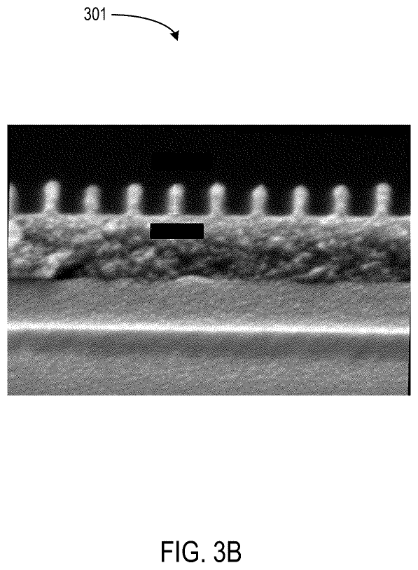

Corresponding to operation 104 of FIG. 1, FIGS. 3A-B show a cross-sectional view 300 and a side view 301 of the example structure of the semiconductor device after hardening the mandrel 204. The mandrel 204 can be hardened (or cured) based on forming a layer 206 along an outer portion of the mandrel 204. For example, the hardening process can involve exposing the (patterned) structure including the underlayer 202 and the mandrel 204 to at least one suitable treatment process, including but not limited to DCS plasma treatment process, UV light treatment process, or CVD treatment process, among others.

The DCS plasma treatment process can be performed in an etch chamber (e.g., a plasma etch chamber or a second chamber) equipped with DCS. The etch chamber may be a different chamber from the processing chamber, e.g., the first chamber different from the second chamber. In some cases, the etch chamber can correspond to or be a part of the processing chamber, e.g., the first chamber including or corresponding to the second chamber. The DCS treatment can be an in-situ process utilizing a reactive gas (RG) plasma with a DC voltage superimposed that can be performed in the etch chamber without breaking the vacuum. For example, as part of the DCS plasma treatment process, voltage (e.g., direct current (DC) voltage) can be applied in the etch chamber to at least one of change the plasma, increase polarization, and/or create ballistic electrons to cure the organics in the substrate or the structure. For instance, the DCS plasma can produce an electron flux or ballistic electron beam and sputter the top electrode material which can deposit as a relatively thin layer of a material (e.g., layer 206) on the mandrel 204, as described herein. The DCS plasma treatment process can cure the mandrel 204 via electron bombardment. The DCS plasma treatment can utilize one or more types of gases for the curing process, including but not limited to H2, Ar, N2, etc. As discussed herein, the silicon (e.g., as part of the protective layer) can be formed from at least one of the gases or from parts or components of the chamber. The voltage applied in the DCS plasma treatment process may be referred to as a DCS voltage. The configuration or parameters for the DCS plasma treatment process can be configured or predetermined. For example, the DCS voltage may range from 200 to 1500 volts. The temperature of the chuck or wafer in the etch chamber can be in a range from 15 to 40 degrees Celsius. The high-frequency radio frequency (RF) source can be in a range from 0.4 to 80 MHz. Other parameters or setup of the etch chamber or the treatment process can be considered, selected, or adjusted according to the desired hardening of the mandrel 204 or the thickness of the layer 206, for example.

Along with curing the mandrel 204, as part of the DCS plasma treatment process, a layer 206 (e.g., a relatively thin layer) of material can be deposited over the outer portions (or exposed portions) of the mandrel 204 and/or the underlayer 202. In some cases, the hardening of the mandrel 204 may refer to the process of forming or depositing the layer 206 over the outer portion of the mandrel 204. The deposited layer 206 in this stage may be referred to as a protective layer or a silicon-based layer. The material of the layer 206 can include or come from a silicon electrode of the plasma source of the DCS plasma treatment process. In some cases, the material of the layer 206 can include or be composed of silicon dioxide, silicon nitride, silicon tetrafluoride (SiF4), silicon oxynitride, amorphous silicon (a-Si), or other types of materials, not limited to those discussed herein. The layer 206 can become oxidized during the hardening of the mandrel 204, such as in the second chamber as part of the DCS plasma treatment process, for example.

The material of the layer 206 can provide protection to the mandrel 204, for instance, at the beginning of the atomic layer conformal deposition process. In some cases, the layer 206 (or other additional or alternative layers) can be deposited using at least one suitable deposition technique, not limited to the deposition via the DCS plasma treatment process. The DCS plasma can be applied to the structure for a predetermined duration (or processing time) depending on the application or hardness level for the mandrel 204. For instance, the predetermined duration for the DCS plasma treatment can include a range from 15 to 25 seconds, a range from 10 to 30 seconds, a range from 31 to 60 seconds, etc. The range can be configurable. In some cases, the thickness of the layer 206 can depend on the processing duration of the DCS plasma treatment process. For example, increasing the processing time for the DCS plasma treatment process can increase the thickness of or introduce a relatively thicker layer 206. In another example, decreasing the processing duration of the DCS plasma treatment process can reduce the thickness of the layer 206.

In some aspects, multiple layers of materials may be deposited over the structure, not limited to the layer 206. For example, the layer 206 may be a first layer of a plurality of layers deposited over the structure (e.g., the patterned mandrel). The other layers can include materials different from the layer 206. One or more other layers deposited over the structure may be provided during, before, or after the DCS plasma treatment process. In some cases, one or more other layers may be deposited or used alternatively to the layer 206.

By hardening at least the outer portion of the mandrel 204 based on forming the layer 206 along the outer portion of the mandrel 204, the structural integrity of the mandrel 204 can be protected during subsequent processing of the structure or semiconductor device. For example, the hardened mandrel 204 can be protected during the spacer deposition stage. Without the treatment process, the pattern (or structure) of the mandrel 204 may potentially collapse or the mandrel 204 itself may potentially be etched during spacer deposition. For example, because the carbon-based mandrel is relatively soft without curing, depositing a spacer layer (e.g., spacer material) may induce excessive stress on the pattern of the carbon-based mandrel resulting in pattern collapse. In another example, because the spacer deposition step etches out the carbon material from the carbon-based mandrel, which is relatively soft without curing, performing the spacer deposition may result in the mandrel being etched out or removed from the structure. Hence, at least one suitable treatment process, such as the DCS plasma treatment process, can be utilized to harden the mandrel 204 to protect the pattern of the mandrel 204 during subsequent operations, including but not limited to the spacer deposition stage. In such cases, the treated, cured, or hardened mandrel 204 can be protected from pattern collapse or mandrel etch out during at least the spacer deposition.

In some configurations, other treatment processes can be utilized in the etch chamber to harden the mandrel 204 or deposit the layer 206 for protecting the mandrel 204. For example, the UV light treatment process may be utilized to cure, harden, or otherwise protect the mandrel 204. Using the UV light treatment process can involve cross-linking any organic that is in the mandrel 204. Depending on at least one of the size of the mandrel 204 or the duration of the UV light treatment, the carbon layers of the mandrel 204 may be hardened as desired. For instance, using the UV light treatment on a relatively wider mandrel can result in hardening the outer portion of the mandrel 204 (without hardening the inner portions). In another instance, using the UV light treatment on the relatively narrower or thinner mandrel may result in hardening of the outer portions and certain inner portions of the mandrel 204. The parameters of the UV light treatment process, such as the duration, wavelength, or intensity of the treatment, can be configured to harden or treat the outer portions of the mandrel 204 or the entire mandrel 204.

In another example, the CVD treatment process can be utilized to harden or protect the mandrel 204. The CVD treatment process can involve depositing at least one film of material onto the substrate or over the structure (e.g., the mandrel 204 and the underlayer 202). In this case, at least one suitable material can be selected for the deposition. The CVD treatment process can be executed to deposit the selected material over the structure. The selected material can be deposited up to a predefined thickness or level. By using at least one of the non-limiting treatment processes discussed herein, the mandrel 204 can be protected for subsequent processing steps to fabricate the semiconductor device. With hardening the mandrel 204 and/or deposition of the layer 206 to protect the mandrel 204, the mandrel 204 can be maintained (or remain present) for spacer deposition process, for example.

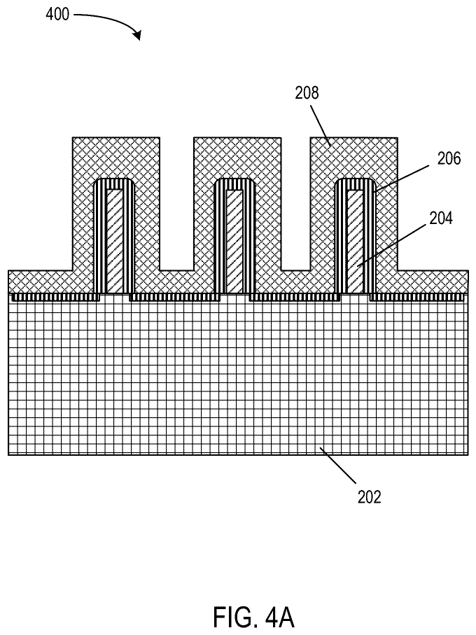

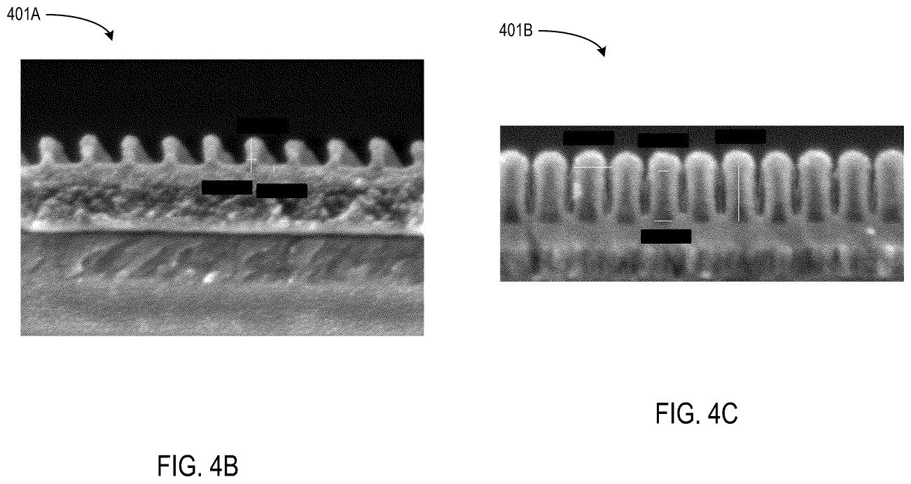

Corresponding to operation 106 of FIG. 1, FIGS. 4A-C show a cross-sectional view 400 and side views 401A-B of the example structure of the semiconductor device after spacer deposition. The side views 401A-B can present images of the example structure after deposing the spacer layer over the hardened mandrel 204 (e.g., hardened organic mandrel) captured by the imaging device (e.g., at the microscopic level). As shown, a spacer layer can be deposited over the hardened mandrel 204 and the layer 206 using at least one suitable deposition technique. The material used as the spacer layer can include but is not limited to silicon oxide, silicon nitride, titanium oxide, or titanium nitride. The deposited spacer layer 208 can allow or enable fabricating other features for the semiconductor device, such as patterning the underlayer 202 or performing double patterning.

The spacer deposition process can be performed in a processing chamber (e.g., a third chamber). The processing chamber for the spacer deposition process can be different from the processing chamber for forming the underlayer 202 and the mandrel 204, e.g., the first chamber and the third chamber are different. In some cases, the processing chamber for the spacer deposition process can be the same processing chamber as the processing chamber for forming the underlayer 202 and the mandrel 204, e.g., the first chamber and the third chamber are the same. Depositing the spacer layer 208 can enlarge the critical dimension (CD) of the structure. For example, the patterned structure can have a relatively wider CD with the spacer layer 208 compared to the patterned structure without the spacer layer 208.

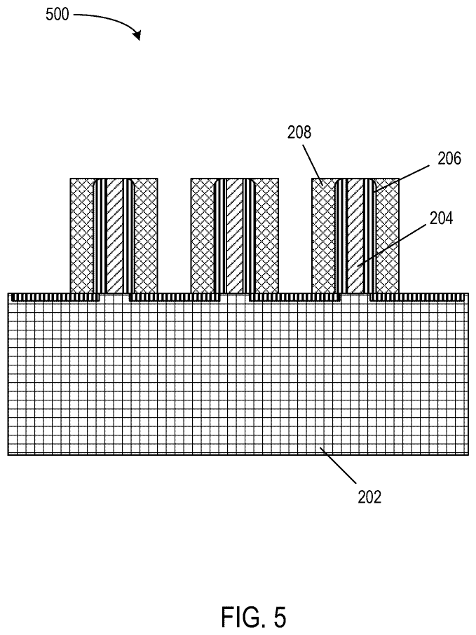

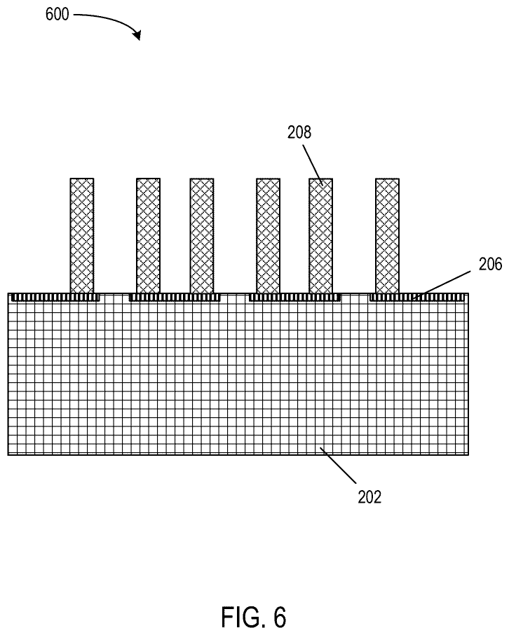

The spacer layer 208 can be formed with a predefined thickness or dimension. In some scenarios, the spacer layer 208 can be trimmed using at least one suitable etching technique to reduce the width of the spacer layer 208 to a predefined width, for example. The spacer layer 208 can be formed or shaped to function as mandrels in subsequent fabrication stages, such as described in conjunction with but not limited to FIGS. 5-6.

In some configurations, after depositing the spacer layer 208, subsequent pre-configured operations for fabricating the semiconductor device can be performed, such as but not limited to spacer patterning or double patterning process. can be performed on the spacer layer 208. For example, FIG. 5 shows a cross-sectional view 500 of the structure after etching portions of the spacer layer 208. In this case, the top portions of the spacer layer 208 can be etched using at least one suitable etching technique. Etching the top portions of the spacer layer 208 (e.g., a first portion of the spacer layer 208) can expose the top surface of at least one of the mandrel 204 and/or the layer 206 (e.g., silicon-based layer). Etching the top portions of the spacer layer 208 (e.g., a second portion of the spacer layer 208) can expose portions of the top surface of the underlayer 202. In some cases, etching the second portion of the spacer layer 208 may expose the layer 206 disposed over the top surface of the underlayer 202. As shown in conjunction with at least FIG. 5, etching the first portion and the second portion of the spacer layer 208 can expose the surfaces of the mandrel 204 and certain portions of the surfaces of the underlayer 202.

With the mandrel 204 exposed, at least one suitable etching technique can be performed to remove the mandrel 204 to pattern the underlayer 202. FIG. 6 shows a cross-sectional view 600 of the structure with the mandrel 204 removed. In some cases, the layer 206 can be removed during the etching process of the mandrel 204. In some other cases, the layer 206 may remain along the sides of the spacer layer 208 after removing the mandrel 204. As shown in conjunction with at least FIG. 6, the remaining spacer layer 208 after removing the mandrel 204 can function as a hard mask (or mandrels) for subsequent processes, including but not limited to patterning the underlayer 202 by utilizing at least one suitable etching technique to etch the exposed portions of the underlayer 202.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
providing a structure comprising an organic mandrel formed in a pattern and an underlying layer;
hardening the organic mandrel including forming a silicon-based layer along an outer portion of the organic mandrel; and
depositing a spacer layer over the hardened organic mandrel.

2. The method of claim 1, further comprising:
etching a first portion of the spacer layer to expose a top surface of the organic mandrel;
etching a second portion of the spacer layer to expose portions of a top surface of the underlying layer, wherein the spacer layer remaining on the structure functions as a hard mask; and
removing the organic mandrel from the structure to pattern the underlying layer.

3. The method of claim 1, wherein providing the structure comprises:
forming the underlying layer above a substrate;
forming the organic mandrel above the underlying layer; and
etching the organic mandrel to form the pattern.

4. The method of claim 1, wherein the silicon-based layer is formed through at least one of a direct current superposition (DCS) plasma treatment process or a chemical vapor deposition (CVD) treatment process.

5. The method of claim 1, wherein the organic mandrel includes carbon.

6. The method of claim 1, wherein the silicon-based layer includes at least one of silicon dioxide, silicon nitride, or silicon oxynitride.

7. The method of claim 1, wherein the silicon-based layer becomes oxidized during the hardening of the organic mandrel.

8. The method of claim 1, wherein forming the structure is performed in a first chamber, hardening the organic mandrel is performed in a second chamber, and depositing the spacer layer is performed in a third chamber.

9. The method of claim 8, wherein the first chamber is same as the second chamber, and the second chamber is different from the third chamber.

10. The method of claim 8, wherein the first chamber is different from the second chamber, and the second chamber is different from the third chamber.

11. The method of claim 1, wherein the spacer layer includes at least one of silicon oxide, silicon nitride, titanium oxide, or titanium nitride.

12. A method, comprising:
providing a patterned structure comprising an organic mandrel and an underlying layer;
forming a protective layer along an outer portion of the organic mandrel to harden the organic mandrel; and
depositing a spacer layer over the patterned structure including the protective layer formed along the outer portion of the organic mandrel.

13. The method of claim 12, further comprising:
etching the spacer layer to expose a top surface of the organic mandrel and portions of a top surface of the underlying layer, wherein the spacer layer remaining on sides of the organic mandrel functions as a hard mask; and
removing the organic mandrel from the patterned structure to pattern the underlying layer.

14. The method of claim 12, wherein providing the patterned structure comprises:
forming the underlying layer above a substrate;
forming the organic mandrel above the underlying layer; and
etching the organic mandrel to form a pattern.

15. The method of claim 12, wherein the protective layer is formed through at least one of a direct current superposition (DCS) plasma treatment process or a chemical vapor deposition (CVD) treatment process.

16. The method of claim 12, wherein the organic mandrel includes carbon, and wherein the protective layer corresponds to a silicon-based layer.

17. A method, comprising:
providing, via a first chamber, a structure comprising an organic mandrel formed in a pattern and an underlying layer;
hardening, via a second chamber, the organic mandrel based on forming a silicon-based layer along an outer portion of the organic mandrel; and
depositing, via a third chamber, a spacer layer over the hardened organic mandrel.

18. The method of claim 17, wherein the first chamber is same as the second chamber, and the second chamber is different from the third chamber.

19. The method of claim 17, wherein the first chamber is different from the second chamber, and the second chamber is different from the third chamber.

20. The method of claim 17, wherein the silicon-based layer includes at least one of silicon dioxide, silicon nitride, or silicon oxynitride, and wherein the spacer layer includes at least one of silicon oxide, silicon nitride, titanium oxide, or titanium nitride.
